(19) United States
(12) Patent Application Publication
(10) Pub. No.: US 2022/0140811 A1
(43) Pub. Date: May 5, 2022

(54) BULK ACOUSTIC WAVE RESONATOR

(71) Applicant: Samsung Electro-Mechanics Co., Ltd., Suwon-si (KR)

(72) Inventors: Tae Kyung LEE, Suwon-si (KR); Dae Hun JEONG, Suwon-si (KR); Ran Hee SHIN, Suwon-si (KR); Jin Suk SON, Suwon-si (KR); Hwa Sun LEE, Suwon-si (KR); Jae Goon AUM, Suwon-si (KR)

(73) Assignee: Samsung Electro-Mechanics Co., Ltd., Suwon-si (KR)

(21) Appl. No.: 17/220,119

(22) Filed: Apr. 1, 2021

(30) Foreign Application Priority Data
Nov. 3, 2020 (KR) 10-2020-0145365

(51) Int. Cl. H03H 9/17; H03H 9/02

(52) U.S. Cl. CPC H03H 9/174; H03H 9/02015; H03H 9/0211; H03H 9/02157; H03H 9/02102

(57) ABSTRACT

A bulk acoustic wave resonator is provided. The resonator includes a substrate; a resonant portion including a first electrode, a piezoelectric layer, and a second electrode sequentially stacked on the substrate; and a temperature compensation layer disposed at least one of above and below the piezoelectric layer, wherein a material of the temperature compensation layer has a coefficient of thermal expansion of which a sign is opposite to a sign of a coefficient of thermal expansion of a material of the piezoelectric layer, and wherein a relation of a thickness of the temperature compensation layer and a thickness of the piezoelectric layer satisfies the following equation: 0.25<Thickness of Temperature Compensation Layer/Thickness of Piezoelectric Layer<0.33.

### CROSS-REFERENCE TO RELATED APPLICATIONS

This application claims the benefit under 35 USC § 119(a) of Korean Patent Application No. 10-2020-0145365 filed on Nov. 3, 2020 in the Korean Intellectual Property Office, the entire disclosure of which is incorporated herein by reference for all purposes.

### BACKGROUND

### 1. Field

The following description relates to a bulk acoustic wave resonator.

### 2. Description of Related Art

In accordance with the trend toward the miniaturization of wireless communications devices, the miniaturization of high frequency component technology has been actively desired. In an example, bulk acoustic wave (BAVV) resonator type filters that implement semiconductor thin film wafer manufacturing technology is being implemented.

Bulk acoustic wave (BAW) resonators refer to a thin film type element that generates resonance using piezoelectric characteristics of a piezoelectric dielectric material deposited on a silicon wafer, which is a semiconductor substrate, and is implemented as a filter.

Recently, interest in fifth-generation (5G) communications technology has increased, and technologies involving the development of bulk acoustic wave resonators that may be implemented in a candidate band, has actively been conducted.

However, in 5G communications implemented with a sub-6 GHz (4 to 6 GHz) frequency band, the bandwidth increases and a communication distance is shortened, such that the signal strength or power of the bulk acoustic wave resonator may increase.

Additionally, a temperature of a piezoelectric layer or a resonant portion may increase due to the increase in the power. In this case, a frequency of the resonant portion fluctuates due to a high temperature, such that stability of the bulk acoustic wave resonator is deteriorated.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a bulk acoustic wave resonator includes a substrate; a resonant portion, comprising a first electrode, a piezoelectric layer, and a second electrode sequentially stacked on the substrate; and a temperature compensation layer disposed at least one of above and below the piezoelectric layer, wherein a material of the temperature compensation layer has a coefficient of thermal expansion of which a sign is opposite to a sign of a coefficient of thermal expansion of a material of the piezoelectric layer, and wherein a relation of a thickness of the temperature compensation layer and a thickness of the piezoelectric layer satisfies the following equation: 0.25<Thickness of Temperature Compensation Layer/Thickness of Piezoelectric Layer<0.33.

A relation between an electromechanical coupling coefficient (Kₜ²) and a temperature coefficient of resonant frequency (TCF), satisfies the following equation: 0.65<|Kₜ²/TCF|.

The temperature compensation layer may include any one of ZrW₂O₈, ZrV₂O₇, ZrMo₂O₈, HfMo₂O₈, HfW₂O₈, HfV₂O₇, Sc(WO₄)₃, LiAlSiO₄, and BiFeO₃.

The temperature compensation layer may be stacked on the second electrode.

The temperature compensation layer may be formed of a material of which a range of an operating temperature at which thermal contraction is generated is 500 K or more.

The bulk acoustic wave resonator may further include an insertion layer partially disposed in the resonant portion, and disposed beneath the piezoelectric layer, wherein at least a portion of the piezoelectric layer and a portion of the second electrode are elevated by the insertion layer.

The resonant portion may include a central portion disposed in a central region of the bulk acoustic wave resonator, and an extension portion disposed along a circumference of the central portion, wherein the insertion layer may be disposed in the extension portion of the resonant portion, wherein the insertion layer may have an inclined surface, and may have a thickness that increases as a distance from the central portion increases, and wherein the piezoelectric layer may have an inclined portion that is disposed on the inclined surface of the insertion layer.

In a cross section of the resonant portion, a distal end of the second electrode may be disposed along a boundary between the central portion and the extension portion, or is disposed on the inclined portion of the piezoelectric layer.

The piezoelectric layer may include a piezoelectric portion disposed in the central portion, and an extending portion that extends outwardly of the inclined portion, and wherein at least a portion of the second electrode is disposed on the extending portion of the piezoelectric layer.

In a general aspect, a bulk acoustic wave resonator includes a substrate; a resonant portion comprising a first electrode, a piezoelectric layer, and a second electrode sequentially stacked on the substrate; and a temperature compensation layer disposed at least one of above and below the piezoelectric layer, wherein the temperature compensation layer is formed of a material having a negative coefficient of thermal expansion, and wherein a relation between an electromechanical coupling coefficient (Kₜ²) and a temperature coefficient of resonant frequency (TCF), satisfies the following equation: 0.65<|Kₜ²/TCF|.

The temperature compensation layer may include any one of ZrW₂O₈, ZrV₂O₇, ZrMo₂O₈, HfMo₂O₈, HfW₂O₈, HfV₂O₇, Sc(WO₄)₃, LiAlSiO₄, and BiFeO₃.

The temperature compensation layer may be stacked on the second electrode.

The temperature compensation layer may be formed of a material of which a range of an operating temperature at which thermal contraction is generated is 500 K or more.

The temperature compensation layer may be disposed below the first electrode.

The bulk acoustic wave resonator may further include a Bragg reflection layer disposed in the substrate, wherein first reflection layers having high acoustic impedance and second reflection layers having low acoustic impedance are alternately stacked in the Bragg reflection layer.

A cavity having a groove shape may be formed in an upper surface of the substrate, and the resonant portion may be disposed to be spaced apart from the substrate by a predetermined distance by the cavity.

In a general aspect, an acoustic resonator includes a substrate; a resonant portion comprising a first electrode, a piezoelectric layer, and a second electrode, which are sequentially stacked; a first temperature compensation layer disposed above the second electrode; and a second temperature compensation layer, disposed between the first electrode and the piezoelectric layer; wherein the first temperature compensation layer and the second compensation layer are formed of a material having a negative coefficient of thermal expansion; wherein the piezoelectric layer is formed of a material having a positive coefficient of thermal expansion; and wherein a relation of a thickness each of the first temperature compensation layer and the second temperature compensation layer, and a thickness of the piezoelectric layer satisfies the following equation: 0.25<Thickness of Temperature Compensation Layer/Thickness of Piezoelectric Layer<0.33.

The second temperature compensation layer may be an insertion layer.

The acoustic resonator may further include a third temperature compensation layer disposed below the first electrode.

A relation between an electromechanical coupling coefficient (Kₜ²) and a temperature coefficient of resonant frequency (TCF), may satisfy the following equation: 0.65<|Kₜ²/TCF|.

Other features and aspects will be apparent from the following detailed description, the drawings, and the claims.

### BRIEF DESCRIPTION OF DRAWINGS

FIG. 1 is a plan view of an example bulk acoustic wave resonator, in accordance with one or more embodiments;

FIG. 2 is a cross-sectional view taken along line I-I′ of FIG. 1;

FIG. 3 is a cross-sectional view taken along line II-II′ of FIG. 1;

FIG. 4 is a cross-sectional view taken along line III-III′ of FIG. 1;

FIG. 5 is a table illustrating operating temperatures of materials having negative coefficients of thermal expansion;

FIGS. 6 and 7 are tables illustrating measurement results of characteristics of a bulk acoustic wave resonator according to a ratio of a thickness of a temperature compensation layer to a thickness of a piezoelectric layer, in accordance with one or more embodiments;

FIG. 8 is graphs illustrating resonator characteristics illustrated in FIGS. 6 and 7;

FIG. 9 is a schematic cross-sectional view illustrating an example bulk acoustic wave resonator, in accordance with one or more embodiments;

FIG. 10 is a schematic cross-sectional view illustrating an example bulk acoustic wave resonator, in accordance with one or more embodiments;

FIG. 11 is a schematic cross-sectional view illustrating an example bulk acoustic wave resonator, in accordance with one or more embodiments; and

FIG. 12 is a schematic cross-sectional view illustrating an example bulk acoustic wave resonator, in accordance with one or more embodiments.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Unless otherwise defined, all terms, including technical and scientific terms, used herein have the same meaning as commonly understood by one of ordinary skill in the art to which this disclosure pertains and after an understanding of the disclosure of this application. Terms, such as those defined in commonly used dictionaries, are to be interpreted as having a meaning that is consistent with their meaning in the context of the relevant art and the disclosure of this application, and are not to be interpreted in an idealized or overly formal sense unless expressly so defined herein.

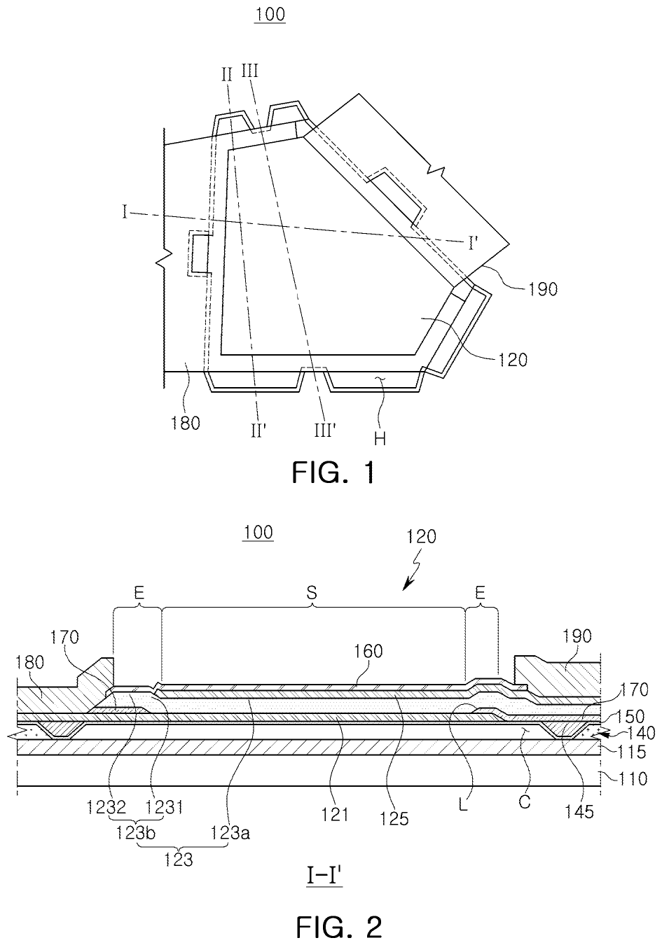

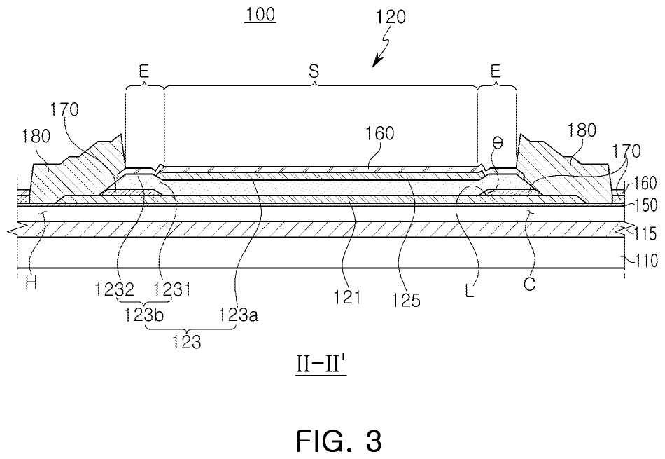

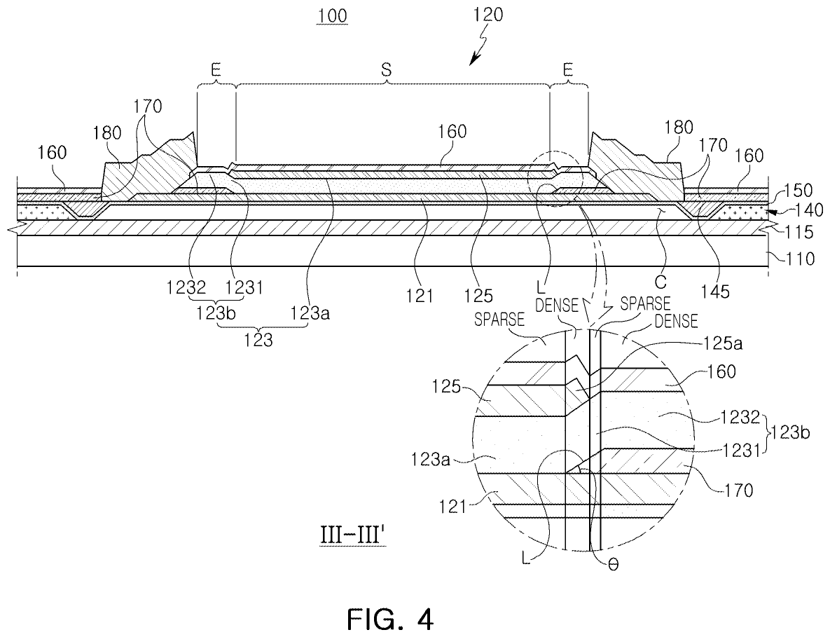

FIG. 1 illustrates a plan view of an example acoustic resonator, in accordance with one or more embodiments, and FIG. 2 is a cross-sectional view taken along line I-I′ of FIG. 1. FIG. 3 is a cross-sectional view taken along line II-II′ of FIG. 1, and FIG. 4 is a cross-sectional view taken along line III-III′ of FIG. 1.

Referring to FIGS. 1 through 4, an acoustic resonator 100, in accordance with one or more embodiments, may be a bulk acoustic wave (BAVV) resonator, and may include a substrate 110, a support layer 140, a resonant portion 120, and an insertion layer 170.

In an example, the substrate 110 may be a silicon substrate. In an example, a silicon wafer or a silicon on insulator (SOI) type substrate may be used as the substrate 110.

An insulating layer 115 may be provided on an upper surface of the substrate 110 to electrically isolate the substrate 110 and the resonant portion 120 from each other. Additionally, the insulating layer 115 may prevent the substrate 110 from being etched by an etching gas at the time of forming a cavity C in a process of manufacturing the acoustic resonator.

In an example, the insulating layer 115 may be formed of at least one of silicon dioxide (SiO₂), silicon nitride (Si₃N₄), aluminum oxide (Al₂O₃), and aluminum nitride (AlN), and may be formed by any one of, but not limited to, a chemical vapor deposition process, a radio frequency (RF) magnetron sputtering process, and an evaporation process.

The support layer 140 may be formed on the insulating layer 115, and may be disposed around a cavity C and an etching preventing portion 145 so as to surround the cavity C and the etching preventing portion 145.

The cavity C may be formed as an empty space, and may be formed by removing a portion of a sacrificial layer formed in a process of preparing the support layer 140.

The etching preventing portion 145 may be disposed along a boundary of the cavity C. The etching preventing portion 145 may be provided in order to prevent etching from being performed beyond a cavity region during a process in which the cavity C is formed.

A membrane layer 150 may be formed on the support layer 140, and may form an upper surface of the cavity C. Therefore, the membrane layer 150 may also be formed of a material that is not easily removed during the process in which the cavity C is formed.

In an example, when a halide based etching gas such as fluorine (F) or chlorine (Cl) is used to remove a portion (for example, a cavity region) of the support layer 140, the membrane layer 150 may be formed of a material of which reactivity to the abovementioned etching gas is low. In this example, the membrane layer 150 may include at least one of a silicon dioxide (SiO₂) and a silicon nitride (Si₃N₄).

Additionally, the membrane layer 150 may be a dielectric layer containing at least one of magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), and zinc oxide (ZnO) or be a metal layer containing at least one of aluminum (Al), nickel (Ni), chromium (Cr), platinum (Pt), gallium (Ga), and hafnium (Hf). However, the membrane layer 150 according to the example is not limited thereto.

The resonant portion 120 may include a first electrode 121, a piezoelectric layer 123, and a second electrode 125. The resonant portion 120 may include the first electrode 121, the piezoelectric layer 123, and the second electrode 125 sequentially stacked from a lower portion to an upper portion thereof. Therefore, in the resonant portion 120, the piezoelectric layer 123 may be disposed between the first electrode 121 and the second electrode 125.

Since the resonant portion 120 is formed on the membrane layer 150, the membrane layer 150, the first electrode 121, the piezoelectric layer 123, and the second electrode 125 may be sequentially stacked on the substrate 110 to form the resonant portion 120.

The resonant portion 120 may resonate the piezoelectric layer 123 according to signals applied to the first electrode 121 and the second electrode 125 to generate a resonant frequency and an anti-resonant frequency.

The resonant portion 120 may be divided into a central portion S in which the first electrode 121, the piezoelectric layer 123, and the second electrode 125 are approximately flatly stacked, and an extension portion E in which the insertion layer 170 is interposed between the first electrode 121 and the piezoelectric layer 123.

The central portion S may be a region disposed at the center of the resonant portion 120, and the extension portion E may be a region disposed along a circumference of the central portion S. Therefore, the extension portion E, which is a region extending outwardly from the central portion S, refers to a region formed in a continuous ring shape along the circumference of the central portion S. Alternatively, the extension portion E may be formed in a discontinuous ring shape of which some regions are disconnected, if necessary.

Therefore, as illustrated in FIG. 2, in a cross-section of the resonant portion 120 cut across the central portion S, the extension portions E may be disposed at both ends of the central portion S, respectively. Additionally, the insertion layer 170 may be inserted into both of the extension portions E disposed at both ends of the central portion S.

The insertion layer 170 may have an inclined surface L so as to have a thickness that increases as a distancer from the central portion S increases.

In the extension portion E, the piezoelectric layer 123 and the second electrode 125 may be disposed on the insertion layer 170. Therefore, the piezoelectric layer 123 and the second electrode 125 positioned in the extension portion E may have inclined surfaces according to a shape of the insertion layer 170.

Meanwhile, in an example, the extension portion E may be included in the resonant portion 120, and thus, resonance may also be generated in the extension portion E. However, a position at which the resonance is generated is not limited thereto. That is, the resonance may not be generated in the extension portion E according to a structure of the extension portion E, and may be generated only in the central portion S.

Each of the first electrode 121 and the second electrode 125 may be formed of a conductor, for example, gold, molybdenum, ruthenium, iridium, aluminum, platinum, titanium, tungsten, palladium, tantalum, chromium, or nickel, or a metal including at least one thereof, but is not limited thereto.

In the resonant portion 120, the first electrode 121 may be formed to have an area greater than an area of the second electrode 125, and a first metal layer 180 may be disposed along an outer side of the first electrode 121 on the first electrode 121. Therefore, the first metal layer 180 may be disposed to be spaced apart from the second electrode 125 by a predetermined distance, and may be disposed to surround the resonant portion 120.

The first electrode 121 may be disposed on the membrane layer 150, and may thus, in a non-limiting example, be entirely flat. On the other hand, the second electrode 125 may be disposed on the piezoelectric layer 123, and may thus have a bent portion that is formed to correspond to a shape of the piezoelectric layer 123.

The first electrode 121 may be used as any one of an input electrode that inputs an electrical signal such as a radio frequency (RF) signal and an output electrode that outputs an electric signal.

The second electrode 125 may be disposed in the entire central portion S, and may be partially disposed in the extension portion E. Therefore, the second electrode 125 may be divided into a portion disposed on a piezoelectric portion 123a of a piezoelectric layer 123 to be described later and a portion disposed on a bent portion 123b of the piezoelectric layer 123.

More specifically, in the example, the second electrode 125 may be disposed to cover the entirety of the piezoelectric portion 123a and a portion of an inclined portion 1231 of the piezoelectric layer 123. Therefore, a second electrode 125a (see FIG. 4) disposed in the extension portion E may have an area smaller than an area of an inclined surface of the inclined portion 1231, and the second electrode 125 may have an area smaller than an area of the piezoelectric layer 123 in the resonant portion 120.

Therefore, as illustrated in FIG. 2, in the cross-section of the resonant portion 120 cut across the central portion S, a distal end of the second electrode 125 may be disposed in the extension portion E. Additionally, at least a portion of the distal end of the second electrode 125 disposed in the extension portion E may be disposed to overlap the insertion layer 170. Herein, the term “overlap” means that when the second electrode 125 is projected on a plane on which the insertion layer 170 is disposed, a shape of the second electrode 125 projected on the plane overlaps the insertion layer 170. Therefore, the distal end of the second electrode 125 may be disposed on the inclined portion.

The second electrode 125 may be used as any one of an input electrode that inputs an electrical signal such as a radio frequency (RF) signal, and an output electrode that outputs an electric signal. That is, when the first electrode 121 is used as the input electrode, the second electrode 125 may be used as the output electrode, and when the first electrode 121 is used as the output electrode, the second electrode 125 may be used as the input electrode.

As illustrated in FIG. 4, when the distal end of the second electrode 125 is positioned on an inclined portion 1231 of a piezoelectric layer 123 to be described later, acoustic impedance of the resonant portion 120 may have a local structure formed in a sparse/dense/sparse/dense structure from the central portion S, and a reflection interface reflecting lateral waves inwardly of the resonant portion 120 may thus be increased. Therefore, most of the lateral waves may not escape outwardly of the resonant portion 120 and may be reflected inwardly of the resonant portion 120, and performance of the acoustic resonator may thus be improved.

The piezoelectric layer 123 may be a portion generating a piezoelectric effect of converting electrical energy into mechanical energy having an elastic wave form, and may be formed on the first electrode 121 and an insertion layer 170 to be described later.

Zinc oxide (ZnO), aluminum nitride (AlN), doped aluminum nitride, lead zirconate titanate, quartz, or the like, may be selectively used as a material of the piezoelectric layer 123. The doped aluminum nitride may further include a rare earth metal, a transition metal, or an alkaline earth metal. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb). In addition, the alkaline earth metal may include magnesium (Mg).

When a content of elements doped in aluminum nitride (AlN) in order to improve piezoelectric characteristics is less than 0.1 at %, piezoelectric characteristics higher than those of aluminum nitride (AlN) may not be implemented, and when a content of elements doped in aluminum nitride (AlN) exceeds 30 at %, it is difficult to perform manufacture and composition control for deposition, such that a non-uniform phase may be formed.

Therefore, the content of elements doped in aluminum nitride (AlN) may be in the range of 0.1 to 30 at %.

In the example, aluminum nitride (AlN) doped with scandium (Sc) may be used as the material of the piezoelectric layer. In this example, a piezoelectric constant may be increased to increase Kₜ² of the acoustic resonator.

The piezoelectric layer 123 according to the example may include the piezoelectric portion 123a disposed in the central portion S and the bent portion 123b disposed in the extension portion E.

The piezoelectric portion 123a may be a portion directly stacked on an upper surface of the first electrode 121. Therefore, the piezoelectric portion 123a may be interposed between the first electrode 121 and the second electrode 125 and be formed to be flat together with the first electrode 121 and the second electrode 125.

The bent portion 123b may refer to a region extending outwardly from the piezoelectric portion 123a and positioned in the extension portion E.

The bent portion 123b may be disposed on an insertion layer 170 to be described later, and may have an upper surface that is raised according to a shape of the insertion layer 170. Therefore, the piezoelectric layer 123 may be bent at a boundary between the piezoelectric portion 123a and the bent portion 123b, and the bent portion 123b may be raised according to a thickness and a shape of the insertion layer 170.

The bent portion 123b may be divided into the inclined portion 1231 and an extending portion 1232.

The inclined portion 1231 may refer to a portion inclined along an inclined surface L of an insertion layer 170 to be described later. Additionally, the extending portion 1232 may refer to a portion that extends outwardly from the inclined portion 1231.

The inclined portion 1231 may be formed in parallel with the inclined surface L of the insertion layer 170, and an inclination angle of the inclined portion 1231 may be the same as an inclination angle of the inclined surface L of the insertion layer 170.

The insertion layer 170 may be disposed along a surface formed by the membrane layer 150, the first electrode 121, and the etching preventing portion 145. Therefore, the insertion layer 170 may be partially disposed in the resonant portion 120, and may be disposed between the first electrode 121 and the piezoelectric layer 123.

The insertion layer 170 may be disposed around the central portion S and support the bent portion 123b of the piezoelectric layer 123. Therefore, the bent portion 123b of the piezoelectric layer 123 may be divided into the inclined portion 1231 and the extending portion 1232 according to the shape of the insertion layer 170.

In the example, the insertion layer 170 may be disposed in a region other than the central portion S. In an example, the insertion layer 170 may be disposed over the entirety of the region other than the central portion S or may be disposed in a portion of the region other than the central portion S on the substrate 110.

The insertion layer 170 may have a thickness that increases as a distance from the central portion S increases. Therefore, a side surface of the insertion layer 170 disposed adjacent to the central portion S may be formed as the inclined surface L having a predetermined inclination angle θ.

When the inclination angle θ of the side surface of the insertion layer 170 is smaller than 5°, a thickness of the insertion layer 170 should be very small or an area of the inclined surface L should be excessively large in order to manufacture the insertion layer 170 of which the inclination angle θ of the side surface is smaller than 5°, which is substantially difficult to be implemented.

Additionally, when the inclination angle θ of the side surface of the insertion layer 170 is greater than 70°, an inclination angle of the piezoelectric layer 123 or the second electrode 125 stacked on the insertion layer 170 may be greater than 70°. In this example, the piezoelectric layer 123 or the second electrode 125 stacked on the inclined surface L may be excessively bent, and a crack may thus occur in a bent portion.

Therefore, in the example, the inclination angle θ of the inclined surface L may be in a range of 5° or more to 70° or less.

In the example, the inclined portion 1231 of the piezoelectric layer 123 may be formed along the inclined surface L of the insertion layer 170, and may thus be formed at the same inclination angle as the inclined surface L of the insertion layer 170. Therefore, the inclination angle of the inclined portion 1231 may also be in a range of 5° or more to 70° or less, similar to the inclined surface L of the insertion layer 170. Such a configuration may also be similarly applied to the second electrode 125 stacked on the inclined surface L of the insertion layer 170.

In an example, the insertion layer 170 may be formed of a dielectric material such as silicon dioxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), or zinc oxide (ZnO), but may be formed of a material different from a material of the piezoelectric layer 123.

Alternatively, the insertion layer 170 may be formed of a metal. When the bulk acoustic wave resonator according to the example is used for 5G communications, a large amount of heat may be generated in the resonant portion, and thus, the heat generated in the resonant portion 120 should be smoothly dissipated. Accordingly, the insertion layer 170 according to the example may be formed of an aluminum alloy material containing scandium (Sc).

Additionally, the insertion layer 170 may be formed of a SiO₂ thin film into which nitrogen (N) or fluorine (F) is injected.

The resonant portion 120 may be disposed to be spaced apart from the substrate 110 through the cavity C formed as the empty space.

The cavity C may be formed by supplying an etching gas (or an etchant) to introduction holes H (see FIG. 1) in the process of manufacturing the acoustic resonator to remove a portion of the support layer 140.

A protective layer 160 may be disposed along a surface of the acoustic resonator 100 to prevent the acoustic resonator 100 from being subjected to damage as a result of external impact. The protective layer 160 may be disposed along a surface formed by the second electrode 125 and the bent portion 123b of the piezoelectric layer 123.

The protective layer 160 may be formed of one layer, but may also be formed by stacking two layers of which materials are different from each other, if necessary. Additionally, the protective layer 160 may be partially removed in order to control a frequency in a final process. In an example, a thickness of the protective layer 160 may be controlled in a frequency trimming process.

In an example, the protective layer 160 may be a dielectric layer containing any one of silicon nitride (Si₃N₄), silicon dioxide (SiO₂), manganese oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), and zinc oxide (ZnO), but is not limited thereto.

Additionally, when the protective layer 160 is formed of a temperature compensation layer to be described later, the protective layer 160 may be formed of any one of ZrW₂O₈, ZrV₂O₇, ZrMo₂O₈, HfMo₂O₈, HfW₂O₈, HfV₂O₇, Sc(WO₄)₃, LiAlSiO₄, and BiFeO₃.

The first electrode 121 and the second electrode 125 may extend outwardly of the resonant portion 120. Additionally, the first metal layer 180 and a second metal layer 190 may be disposed on upper surfaces of the extending portions, respectively.

Each of the first metal layer 180 and the second metal layer 190 may be formed of any one of gold (Au), a gold-tin (Au—Sn) alloy, copper (Cu), a copper-tin (Cu—Sn) alloy, aluminum (Al), and an aluminum alloy. Here, the aluminum alloy may be an aluminum-germanium (Al—Ge) alloy or an aluminum-scandium (Al—Sc) alloy.

The first metal layer 180 and the second metal layer 190 may be implemented as connection wirings electrically connecting the first and second electrodes 121 and 125 of the bulk acoustic wave resonator, according to the example, to electrodes of another bulk acoustic wave resonator disposed adjacent to the bulk acoustic wave resonator according to the example on the substrate 110.

The first metal layer 180 may penetrate through the protective layer 160, and may then be bonded to the first electrode 121.

Additionally, in the resonant portion 120, the first electrode 121 may be formed to have an area greater than an area of the second electrode 125, and the first metal layer 180 may be formed at a circumferential portion of the first electrode 121.

Therefore, the first metal layer 180 may be disposed along a circumference of the resonant portion 120 to thus surround the second electrode 125. However, the first metal layer 180 is not limited thereto.

In the example, the protective layer 160 positioned on the resonant portion 120 may be disposed so that at least a portion thereof is in contact with the first metal layer 180 and the second metal layer 190. The first metal layer 180 and the second metal layer 190 may be formed of a metal having a high thermal conductivity and may have a large volume to thus have an excellent heat dissipation effect.

Therefore, the protective layer 160 may be connected to the first metal layer 180 and the second metal layer 190 so that heat generated in the piezoelectric layer 123 may be rapidly transferred to the first metal layer 180 and the second metal layer 190 via the protective layer 160.

In an example, at least portions of the protective layer 160 may be disposed beneath the first metal layer 180 and the second metal layer 190. Specifically, the protective layer 160 may be inserted between the first metal layer 180 and the piezoelectric layer 123 and between the second metal layer 190, and the second electrode 125 and the piezoelectric layer 123.

The resonant portion 120 configured as described above may be disposed to be spaced apart from the substrate 110 through the cavity C disposed beneath the membrane layer 150 Therefore, the membrane layer 150 may be disposed beneath the first electrode 121 and the insertion layer 170 to support the resonant portion 120.

The cavity C may be formed as an empty space, and may be formed by supplying an etching gas (or an etchant) to introduction holes H (see FIG. 1) in the process of manufacturing the acoustic resonator to remove a portion of the support layer 140.

The bulk acoustic wave resonator 100 according to the example may include at least one temperature compensation layer. Most of materials of components constituting the resonant portion 120 according to the example may have a positive coefficient of thermal expansion (CTE). Therefore, as a temperature of the resonant portion 120 increases, a volume of the resonant 120 may increase, which may have an influence on a frequency of the resonant portion 120.

Therefore, in the bulk acoustic wave resonator 100 according to the example, a frequency fluctuation may be significantly decreased by offsetting and compensating for thermal expansion characteristics due to the materials having the positive coefficient of thermal expansion through the temperature compensation layer. Therefore, the temperature compensation layer according to the example may be formed of a material having a negative coefficient of thermal expansion.

The piezoelectric layer 123 may occupy the largest volume of the resonant portion 120. Therefore, the temperature compensation layer according to the example may be formed of a material having a coefficient of thermal expansion of which a sign is opposite to a sign of a coefficient of thermal expansion of a material of the piezoelectric layer 123, and may be disposed above or below the piezoelectric layer 123.

Therefore, the piezoelectric layer 123 may be formed of a material having a positive coefficient of thermal expansion, and the temperature compensation layer may be formed of a material having a negative coefficient of thermal expansion.

When the temperature compensation layer is formed of the material having the negative coefficient of thermal expansion, a volume of the temperature compensation layer may be contracted (for example, thermally contracted) as a temperature increases, and may thus offset and compensate for thermal expansion characteristics of the piezoelectric layer. Therefore, an elastic modulus of the resonant portion may be increased, and a fluctuation of a resonant frequency may thus be suppressed.

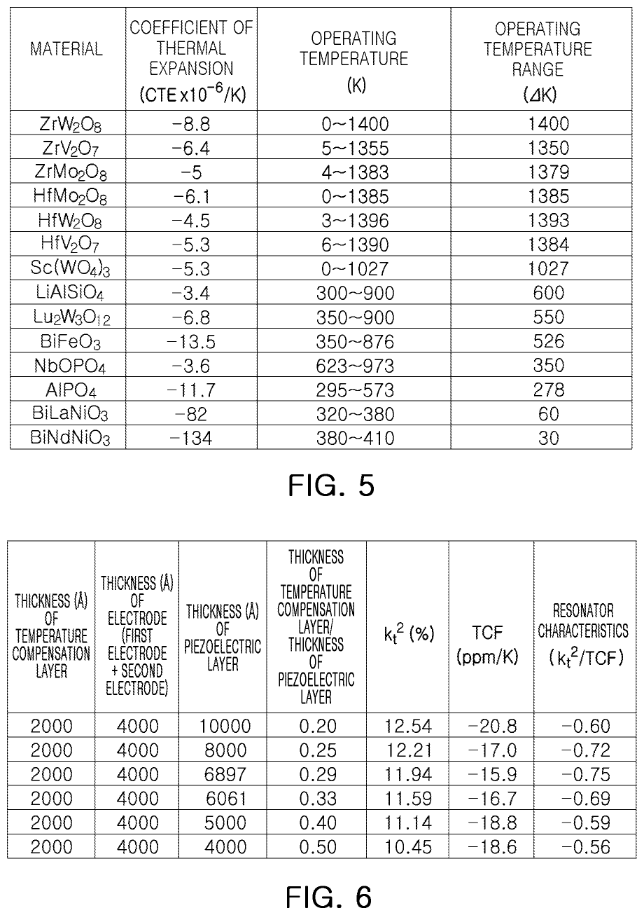

FIG. 5 is a table illustrating operating temperatures of materials having negative coefficients of thermal expansion.

Referring to FIG. 5, materials of which absolute values of coefficients of thermal expansion are large may be BiLaNiO₃ and BiNdNiO₃. However, an operating temperature range (a difference (AK) between a maximum operating temperature and a minimum operating temperature) of these materials may be 100 K or less, which is very narrower than an operating temperature range of the other materials.

Additionally, in the bulk acoustic wave resonator according to the example, a fluctuation range of a temperature may be 500 K or more according to a magnitude of applied power, and it may thus be advantageous to use a material of which a range of an operating temperature is 500 K or more.

Therefore, the temperature compensation layer according to the example may include any one of ZrW₂O₈, ZrV₂O₇, ZrMo₂O₈, HfMo₂O₈, HfW₂O₈, HfV₂O₇, Sc(WO₄)₃, LiAlSiO₄, and BiFeO₃ of which ranges (ΔK) of operating temperatures are 500 K or more among materials disclosed in FIG. 5.

In the bulk acoustic wave resonator according to the example, the protective layer 160 described above may be formed as the temperature compensation layer. However, at least one of the membrane layer 150 disposed beneath the first electrode 121, the insertion layer 170, and the etching preventing portion 145 may also be formed as the temperature compensation layer, if necessary.

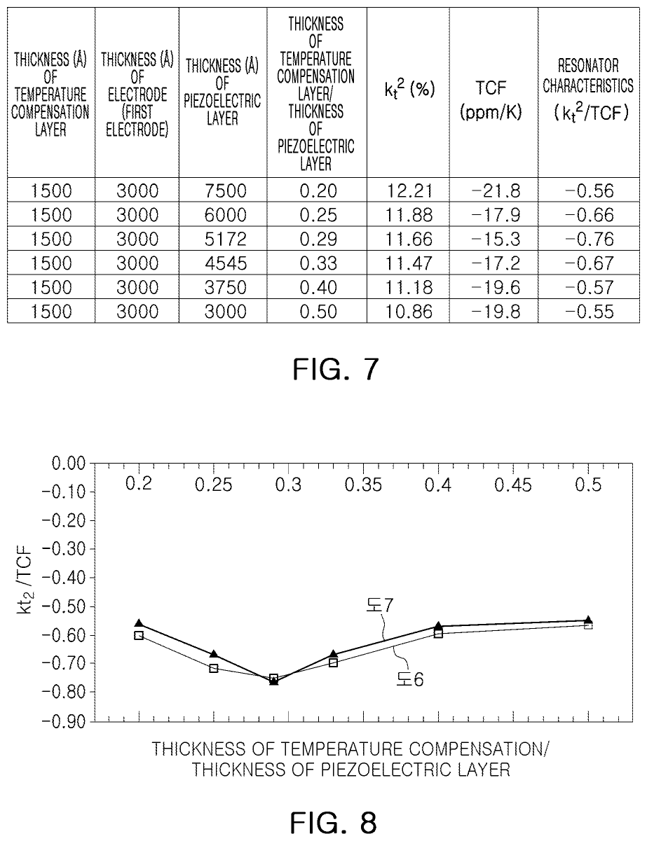

FIGS. 6 and 7 are tables illustrating measurement results of characteristics of a bulk acoustic wave resonator according to a ratio of a thickness of a temperature compensation layer to a thickness of a piezoelectric layer. The characteristics of the bulk acoustic wave resonator in which the protective layer is formed as the temperature compensation layer were measured. FIG. 6 is a table illustrating measurement results in a state of fixing a thickness of the temperature compensation layer to 2000 Å while changing a thickness of the piezoelectric layer, and FIG. 7 is a table illustrating measurement results in a state of fixing a thickness of the temperature compensation layer to 1500 Å while changing a thickness of the piezoelectric layer.

Additionally, FIG. 8 is a graph illustrating resonator characteristics illustrated in FIGS. 6 and 7.

Referring to FIGS. 6 through 8, it can be seen that Kₜ² (electromechanical coupling coefficient) increases as a whole as the ratio of the thickness of the temperature compensation layer to the thickness of the piezoelectric layer becomes smaller. Since Kₜ² has the-larger-the-better characteristics, which are characteristics that improve as an absolute value becomes larger, it may be advantageous to significantly decrease a value of the ratio of the thickness of the temperature compensation layer to the thickness of the piezoelectric layer in order to improve characteristics of Kₜ².

Additionally, generally, a resonant frequency of the bulk acoustic wave resonator tends to decrease as a temperature increases. A temperature coefficient of resonant frequency (TCF), which is characteristics representing a gradual change of the resonant frequency according to the temperature, it is advantageous to keep the TCF close to 0.

When the TCF characteristics are bad (for example, when an absolute value of the TCF increases), a fluctuation of the resonant frequency may increase according to a temperature change, which may act as a fatal factor that may damage the bulk acoustic wave resonator.

The TCF has the-smaller-the-better characteristics, which are characteristics becoming better as an absolute value becomes smaller. Therefore, referring to FIGS. 6 and 7, it can be seen that the TCF has the best characteristics in a section in which the ratio of the thickness of the temperature compensation layer to the thickness of the piezoelectric layer is 0.25 to 0.33.

When only the Kₜ² characteristics are considered, the TCF characteristics may be excessively deteriorated. Conversely, when only the TCF characteristics are considered, the Kₜ² characteristics may be excessively deteriorated.

Therefore, in order to consider the Kₜ² characteristic and the TCF characteristic at the same time, in the example, a value (Kₜ²/TCF) (hereinafter, referred to as resonator characteristic) obtained by dividing a Kₜ² value by a TCF value may be defined as a main factor. In this case, since the-larger-the-better characteristics are divided by the-smaller-the-better characteristics, it may be understood that entire resonator characteristics may be improved as an absolute value of the resonator characteristics becomes larger.

Referring to FIGS. 5 through 8, an absolute value of the resonator characteristic (Kₜ²/TCF) may be the largest in the section in which the ratio of the thickness of the temperature compensation layer to the thickness of the piezoelectric layer is 0.25 to 0.33. In such a section, the absolute value of the resonator characteristics (Kₜ²/TCF) was measured to be 0.65 or more, and it was confirmed that the same trend was observed in both of a case of performing measurement in a state of fixing the thickness of the temperature compensation layer to 2000 Å and a case of performing measurement in a state of fixing the thickness of the temperature compensation layer to 1500 Å.

Therefore, in the bulk acoustic wave resonator according to the example, it can be seen that a decrease in Kₜ² may be significantly decreased and the TCF characteristics may be significantly increased in the section in which the ratio of the thickness of the temperature compensation layer to the thickness of the piezoelectric layer is 0.25 to 0.33.

Therefore, the bulk acoustic wave resonator according to the example including the temperature compensation layer may satisfy the following Equation 1 in relation to the thicknesses of the temperature compensation layer and the piezoelectric layer:

0.25<Thickness of Temperature Compensation Layer/Thickness of Piezoelectric Layer<0.33. Equation 1:

Additionally, the bulk acoustic wave resonator according to the example including the temperature compensation layer may satisfy the following Equation 2 in relation to Kₜ² (electromechanical coupling coefficient) and the temperature coefficient of resonant frequency (TCF):

0.65<|Kₜ²/TCF|. Equation 2:

When the ratio of the thickness of the temperature compensation layer to the thickness of the piezoelectric layer 123 is out of the range of Equation 1, Kₜ² may be excessively decreased or the TCF characteristics may be excessively decreased, such that it may be difficult to secure stability of the bulk acoustic wave resonator. Therefore, in the bulk acoustic wave resonator according to the example, the thickness of the temperature compensation layer and the thickness of the piezoelectric layer 123 may be defined within the range in which Equation 1 is satisfied.

However, the examples are not limited to the abovementioned examples, but may be variously modified.

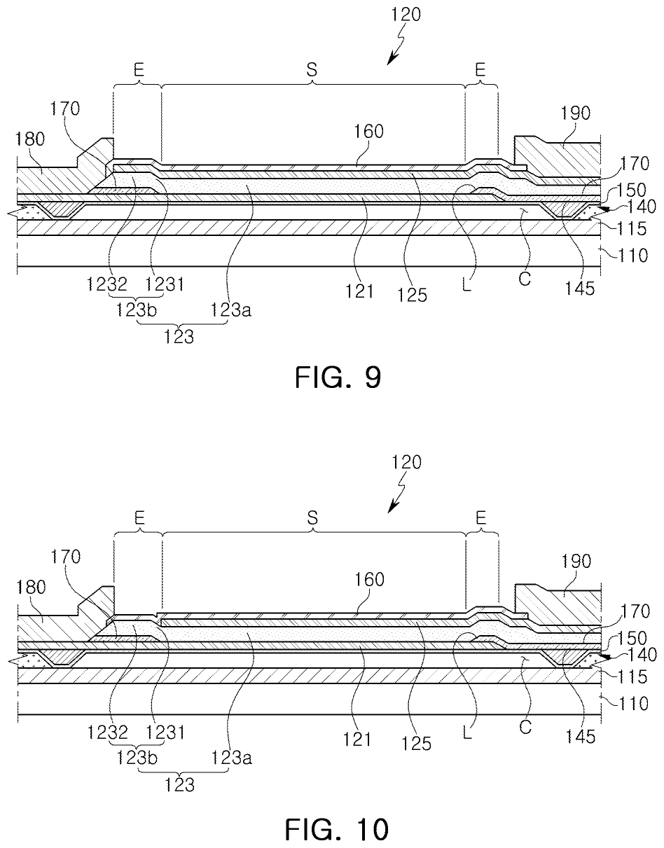

FIG. 9 is a schematic cross-sectional view illustrating a bulk acoustic wave resonator, in accordance with one or more embodiments.

In the bulk acoustic wave resonator illustrated in the example, the second electrode 125 may be disposed over the entirety of an upper surface of the piezoelectric layer 123 within the resonant portion 120. Therefore, the second electrode 125 may be formed on the extending portion 1232 of the piezoelectric layer 123 as well as on the inclined portion 1231 of the piezoelectric layer 123.

FIG. 10 is a schematic cross-sectional view illustrating an example bulk acoustic wave resonator, in accordance with one or more embodiments.

Referring to FIG. 10, in the bulk acoustic wave resonator according to the example, in a cross section of the resonant portion 120 cut across the central portion S, a distal end of the second electrode 125 may be formed only on an upper surface of the piezoelectric portion 123a of the piezoelectric layer 123, and may not be formed on the bent portion 123b of the piezoelectric layer 123. Therefore, the distal end of the second electrode 125 may be disposed along a boundary between the central portion S and the extension portion E partitioning the piezoelectric portion 123a and the inclined portion 1231.

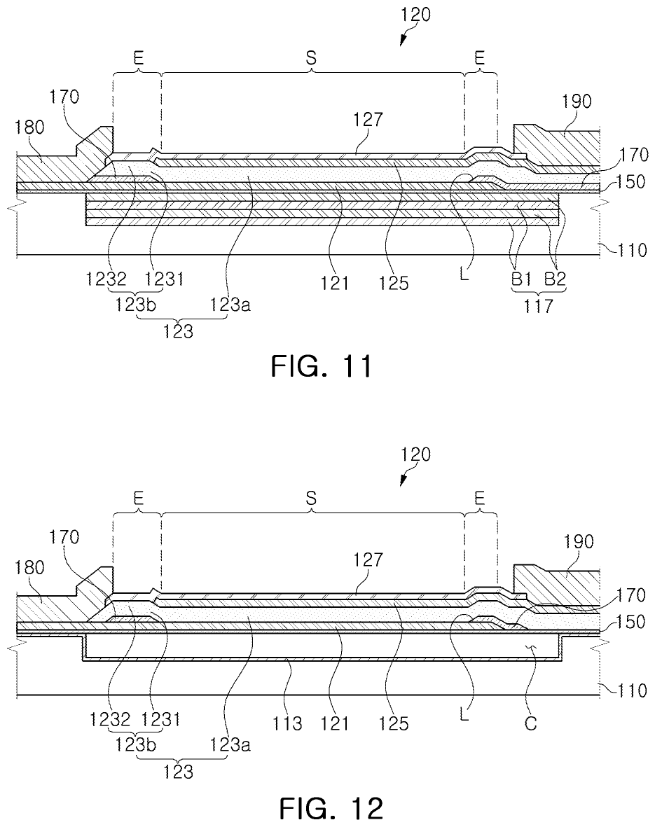

FIG. 11 is a schematic cross-sectional view illustrating an example bulk acoustic wave resonator, in accordance with one or more embodiments.

Referring to FIG. 11, the example bulk acoustic wave resonator may be formed similar to the example acoustic resonator illustrated in FIGS. 2 and 3. However, the example bulk acoustic wave resonator as illustrated in FIG. 11 may not include a cavity C (see FIG. 2), and may include a Bragg reflection layer 117.

The Bragg reflection layer 117 may be disposed in the substrate 110 and may be formed by alternately stacking first reflection layers B1 having high acoustic impedance and second reflection layers B2 having low acoustic impedance below the resonant portion 120.

In this example, the first reflection layer B1 and the second reflection layer B2 may have thicknesses that are determined according to a specific wavelength to reflect acoustic waves toward the resonant portion 120 in a vertical direction, thereby blocking the acoustic waves from flowing out downwardly of the substrate 110.

Accordingly, the first reflection layer B1 may be formed of a material having a density higher than a density of the second reflection layer B2. In an example, any one of W, Mo, Ru, Ir, Ta, Pt, and Cu may selectively be used as the material of the first reflection layer B1. Additionally, the second reflection layer B2 may be formed of a material having a density lower than that of the first reflection layer B1. In an example, any one of SiO₂, Si₃N₄, and AlN may selectively be used as the material of the second reflection layer B2. However, the materials of the first and second reflection layers are not limited thereto.

FIG. 12 is a schematic cross-sectional view illustrating an example bulk acoustic wave resonator, in accordance with one or more embodiments.

Referring to FIG. 12, the bulk acoustic wave resonator according to the example may be formed similar to the acoustic resonator illustrated in FIGS. 2 and 3. However, in the example bulk acoustic wave resonator illustrated in FIG. 12, a cavity C may not be formed above the substrate 110, but may instead be formed in the substrate 110, and may be formed by partially removing the substrate 110.

The cavity C according to the example may be formed by partially etching an upper surface of the substrate 110. Both of dry etching or wet etching may be used as the etching of the substrate 110.

A barrier layer 113 may be formed on an inner surface of the cavity C. The barrier layer may protect the substrate 110 from an etchant used in a process of forming the resonant portion 120.

The barrier layer 113 may be formed of a dielectric material such as AlN or SiO₂, but is not limited thereto. That is, various materials may be used as the material of the barrier layer 113 as long as they may protect the substrate 110 from the etchant.

As described above, the example bulk acoustic wave resonator may be modified in various forms, if necessary.

As set forth above, in the bulk acoustic wave resonator according to the example, the temperature compensation layer may be provided to suppress thermal expansion of the resonant portion. Therefore, a change in a frequency of the resonant portion due to the thermal expansion may be suppressed, and frequency stability of the bulk acoustic wave resonator may thus be secured even in an environment in which high power is applied to the bulk acoustic wave resonator.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic wave resonator, comprising:
a substrate;
a resonant portion, comprising a first electrode, a piezoelectric layer, and a second electrode sequentially stacked on the substrate; and
a temperature compensation layer disposed at least one of above and below the piezoelectric layer,
wherein a material of the temperature compensation layer has a coefficient of thermal expansion of which a sign is opposite to a sign of a coefficient of thermal expansion of a material of the piezoelectric layer, and
wherein a relation of a thickness of the temperature compensation layer and a thickness of the piezoelectric layer satisfies the following equation: 0.25<Thickness of Temperature Compensation Layer/Thickness of Piezoelectric Layer<0.33.

2. The bulk acoustic wave resonator of claim 1, wherein a relation between an electromechanical coupling coefficient (Kₜ²) and a temperature coefficient of resonant frequency (TCF), satisfies the following equation: 0.65<|Kₜ²/TCF|.

3. The bulk acoustic wave resonator of claim 1, wherein the temperature compensation layer comprises any one of ZrW₂O₈, ZrV₂O₇, ZrMo₂O₈, HfMo₂O₈, HfW₂O₈, HfV₂O₇, Sc(WO₄)₃, LiAlSiO₄, and BiFeO₃.

4. The bulk acoustic wave resonator of claim 2, wherein the temperature compensation layer is stacked on the second electrode.

5. The bulk acoustic wave resonator of claim 1, wherein the temperature compensation layer is formed of a material of which a range of an operating temperature at which thermal contraction is generated is 500 K or more.

6. The bulk acoustic wave resonator of claim 1, further comprising an insertion layer partially disposed in the resonant portion, and disposed beneath the piezoelectric layer,
wherein at least a portion of the piezoelectric layer and a portion of the second electrode are elevated by the insertion layer.

7. The bulk acoustic wave resonator of claim 6, wherein the resonant portion comprises a central portion disposed in a central region of the bulk acoustic wave resonator, and an extension portion disposed along a circumference of the central portion,
wherein the insertion layer is disposed in the extension portion of the resonant portion,
wherein the insertion layer has an inclined surface, and has a thickness that increases as a distance from the central portion increases, and
wherein the piezoelectric layer has an inclined portion that is disposed on the inclined surface of the insertion layer.

8. The bulk acoustic wave resonator of claim 7, wherein in a cross section of the resonant portion, a distal end of the second electrode is disposed along a boundary between the central portion and the extension portion, or is disposed on the inclined portion of the piezoelectric layer.

9. The bulk acoustic wave resonator of claim 7, wherein the piezoelectric layer comprises a piezoelectric portion disposed in the central portion, and an extending portion that extends outwardly of the inclined portion, and
wherein at least a portion of the second electrode is disposed on the extending portion of the piezoelectric layer.

10. A bulk acoustic wave resonator, comprising:
a substrate;
a resonant portion comprising a first electrode, a piezoelectric layer, and a second electrode sequentially stacked on the substrate; and
a temperature compensation layer disposed at least one of above and below the piezoelectric layer,
wherein the temperature compensation layer is formed of a material having a negative coefficient of thermal expansion, and
wherein a relation between an electromechanical coupling coefficient (Kₜ²) and a temperature coefficient of resonant frequency (TCF), satisfies the following equation: 0.65<|Kₜ²/TCF|.

11. The bulk acoustic wave resonator of claim 10, wherein the temperature compensation layer comprises any one of ZrW₂O₈, ZrV₂O₇, ZrMo₂O₈, HfMo₂O₈, HfW₂O₈, HfV₂O₇, Sc(WO₄)₃, LiAlSiO₄, and BiFeO₃.

12. The bulk acoustic wave resonator of claim 10, wherein the temperature compensation layer is stacked on the second electrode.

13. The bulk acoustic wave resonator of claim 10, wherein the temperature compensation layer is formed of a material of which a range of an operating temperature at which thermal contraction is generated is 500 K or more.

14. The bulk acoustic wave resonator of claim 10, wherein the temperature compensation layer is disposed below the first electrode.

15. The bulk acoustic wave resonator of claim 10, further comprising a Bragg reflection layer disposed in the substrate,
wherein first reflection layers having high acoustic impedance and second reflection layers having low acoustic impedance are alternately stacked in the Bragg reflection layer.

16. The bulk acoustic wave resonator of claim 10, wherein a cavity having a groove shape is formed in an upper surface of the substrate, and
the resonant portion is disposed to be spaced apart from the substrate by a predetermined distance by the cavity.

17. An acoustic resonator, comprising:
a substrate;
a resonant portion comprising a first electrode, a piezoelectric layer, and a second electrode, which are sequentially stacked;
a first temperature compensation layer disposed above the second electrode; and
a second temperature compensation layer, disposed between the first electrode and the piezoelectric layer;
wherein the first temperature compensation layer and the second compensation layer are formed of a material having a negative coefficient of thermal expansion;
wherein the piezoelectric layer is formed of a material having a positive coefficient of thermal expansion; and
wherein a relation of a thickness each of the first temperature compensation layer and the second temperature compensation layer, and a thickness of the piezoelectric layer satisfies the following equation: 0.25<Thickness of Temperature Compensation Layer/Thickness of Piezoelectric Layer<0.33.

18. The acoustic resonator of claim 17, wherein the second temperature compensation layer is an insertion layer.

19. The acoustic resonator of claim 17, further comprising a third temperature compensation layer disposed below the first electrode.

20. The acoustic resonator of claim 17, wherein a relation between an electromechanical coupling coefficient (Kₜ²) and a temperature coefficient of resonant frequency (TCF), satisfies the following equation: 0.65<|Kₜ²/TCF|.
